(19) United States
(12) Patent Application Publication
(10) Pub. No.: US 2025/0068508 A1
(43) Pub. Date: Feb. 27, 2025

(54) STORAGE SYSTEM, MEMORY CHIP, AND ERROR CHECK AND SCRUB METHOD

(71) Applicant: CXMT CORPORATION, Hefei (CN)

(72) Inventors: Kai SUN, Hefei (CN); Zequn HUANG, Hefei (CN)

(21) Appl. No.: 18/946,971

(22) Filed: Nov. 14, 2024

Related U.S. Application Data
(63) Continuation of application No. PCT/CN2023/131596, filed on Nov. 14, 2023.

(30) Foreign Application Priority Data
Mar. 17, 2023 (CN) 202310277268.9

(51) Int. Cl. G06F 11/07

(52) U.S. Cl. CPC G06F 11/0793; G06F 11/073

(57) ABSTRACT

Provided are a storage system, a memory chip, and an error check and scrub method. The storage system includes a memory controller and a memory chip. The memory chip performs an error check and scrub ECS operation on a memory array; and sends a generated ECS finish flag signal to the memory controller after a current ECS operation is completed. The memory controller receives the ECS finish flag signal, and sends a generated ECS start flag signal to the memory chip based on the ECS finish flag signal, so that the memory chip enters a new ECS operation cycle.

### CROSS-REFERENCE TO RELATED APPLICATIONS

The present disclosure is a continuation of International Patent Application No. PCT/CN2023/131596, filed on Nov. 14, 2023, which claims priority to Chinese Patent Application No. 202310277268.9, filed with the China National Intellectual Property Administration on Mar. 17, 2023 and entitled “STORAGE SYSTEM, MEMORY CHIP, AND ERROR CHECK AND SCRUB METHOD”, which is incorporated herein by reference in its entirety.

### TECHNICAL FIELD

The present disclosure relates to but is not limited to a storage system, a memory chip, and an error check and scrub method.

### BACKGROUND

As the semiconductor technology continuously develops, because the transmission speed of a memory becomes faster, a memory cell shrinks, row hammer occurs, and so on, an error may occur in the memory. Therefore, error check needs to be performed on the memory and a checked error needs to be corrected in a timely manner. A dynamic random access memory (DRAM) is taken as an example. Complete error check and scrub (ECS) needs to be performed on the DRAM for at least one time every 24 hours. However, how to better perform an ECS operation in the DRAM to control a related process of the ECS operation is a problem that needs to be resolved.

### SUMMARY

The present disclosure provides a storage system, a memory chip, and an error check and scrub method.

The technical solutions of the present disclosure are implemented as follows:

According to a first aspect, an embodiment of the present disclosure provides a storage system. The storage system includes a memory chip and a memory controller.

The memory chip includes a memory array, and is configured to: perform an error check and scrub ECS operation on the memory array; and generate an ECS finish flag signal and send the ECS finish flag signal to the memory controller after the current ECS operation is completed. The memory controller is connected to the memory chip, and is configured to: receive the ECS finish flag signal, generate an ECS start flag signal based on the ECS finish flag signal, and send the ECS start flag signal to the memory chip, so that the memory chip enters a new ECS operation cycle based on the ECS start flag signal.

In some embodiments, the memory chip is specifically configured to: generate multiple ECS command signals and perform one error check and scrub ECS operation on a memory cell corresponding to each storage address based on the ECS command signal in the ECS operation cycle; and complete the current ECS operation and generate check result information after the error check and scrub ECS operation is performed on memory cells corresponding to all the storage addresses. The memory controller is further configured to: receive the check result information, and perform a processing operation on the memory chip based on the check result information. The check result information includes an error count of a row with a largest quantity of errors, an address of a row with the largest quantity of errors, and a cumulative value of errors/cumulative value of rows with an error.

In some embodiments, the memory chip includes an ECS circuit and a first register circuit, and the ECS circuit includes a command generation circuit and a counting circuit. The command generation circuit is configured to generate one ECS command signal by adopting one refresh command at an interval in the ECS operation cycle. The adopted refresh command disappears. The counting circuit is connected to the command generation circuit, and is configured to: count the ECS command signal, to generate an address count value, one address count value indicating one storage address; and generate the ECS finish flag signal when the address count value reaches a first preset value, and send the ECS finish flag signal to the first register circuit. The first register circuit is connected to the counting circuit, and is configured to: store the ECS finish flag signal, and send the ECS finish flag signal to the memory controller in response to a mode register read command received from the memory controller.

In some embodiments, the memory chip further includes a recording circuit. The recording circuit is connected to the counting circuit, and is configured to: store error information; and generate the check result information based on the error information when the ECS finish flag signal is received, and send the check result information to the first register circuit. The error information is updated in the ECS operation cycle based on the address count value corresponding to each ECS operation and a check result of a memory cell corresponding to the address count value. The first register circuit is connected to the recording circuit, and is further configured to: store the check result information, and send the check result information to the memory controller.

In some embodiments, the memory chip further includes a second register circuit and a start circuit. The second register circuit is configured to store an ECS configuration parameter. The start circuit is connected to the memory controller and the second register circuit, and is configured to parse the ECS configuration parameter when the ECS start flag signal sent by the memory controller is received, to generate an ECS start signal. The ECS circuit is connected to the start circuit, and is configured to: receive the ECS start signal, and control, based on the ECS start signal, the memory chip to enter a new ECS operation cycle.

In some embodiments, the memory controller is further configured to generate and send an interval adjustment signal based on the check result information. The memory chip is further configured to: receive the interval adjustment signal, and adjust a time interval between two consecutive ECS command signals based on the interval adjustment signal.

In some embodiments, the command generation circuit includes a first command generation circuit and a second command generation circuit. The first command generation circuit is connected to the start circuit, and is configured to: receive the refresh command, and generate one ECS command signal by adopting a next refresh command at an interval. The second command generation circuit is connected to the first command generation circuit, and is configured to: receive the ECS command signal, and generate an internal command signal based on the ECS command signal. The counting circuit is specifically configured to increase the address count value by one each time one internal command signal is received.

In some embodiments, the first command generation circuit is specifically configured to: receive a preset clock signal and the refresh command and generate one ECS command signal by adopting a next refresh command when a first quantity of clock cycles of the preset clock signal pass. A clock cycle length of the preset clock signal is controlled by the interval adjustment signal, and/or the first quantity is controlled by the interval adjustment signal.

In some embodiments, the first command generation circuit is specifically configured to: receive the refresh command, and generate one ECS command signal by adopting a next refresh command at an interval of a second quantity of refresh commands. The second quantity is controlled by the interval adjustment signal.

In some embodiments, the counting circuit includes a column counting circuit, a row counting circuit, and a bank counting circuit, and the address count value includes a column count value, a row count value, and a bank count value. The column counting circuit is connected to the second command generation circuit, and is configured to: receive the internal command signal; count the internal command signal to generate the column count value; increase the column count value by one each time one internal command signal is received; and output one row counting signal and reset the column count value to zero when the column count value reaches a second preset value. The row counting circuit is connected to the column counting circuit, and is configured to: receive the row counting signal; count the row counting signal to generate the row count value; increase the row count value by one each time one row counting signal is received; and output one bank counting signal and reset the row count value to zero when the row count value reaches a third preset value. The bank counting circuit is connected to the row counting circuit, and is configured to: receive the bank counting signal; count the bank counting signal to generate the bank count value; increase the bank count value by one each time one bank counting signal is received; and output one ECS finish flag signal when the bank count value reaches a fourth preset value. The first preset value includes the second preset value, the third preset value, and the fourth preset value.

In some embodiments, the counting circuit is further configured to reset the address count value to zero after the memory chip receives the ECS start flag signal.

In some embodiments, the memory controller is further configured to send first processing information to the memory chip when the check result information is received. The first processing information indicates to skip a row corresponding to the address of the row with the largest quantity of errors when writing into the memory array is performed.

In some embodiments, the memory controller is further configured to send second processing information to the memory chip when the check result information is received. The second processing information indicates to perform redundancy repair processing on the row corresponding to the address of the row with the largest quantity of errors.

According to a second aspect, an embodiment of the present disclosure provides a memory chip. The memory chip includes a memory array and a control circuit, and the memory array is connected to the control circuit. The control circuit is configured to: perform an error check and scrub ECS operation on the memory array; and generate an ECS finish flag signal and send the ECS finish flag signal to the outside after a current ECS operation cycle is completed; and receive an ECS start flag signal from the outside, and enter a new ECS operation cycle based on the ECS start flag signal.

In some embodiments, the control circuit is specifically configured to: generate multiple ECS command signals and perform an error check and scrub ECS operation on a memory cell corresponding to each storage address based on the ECS command signal in the ECS operation cycle; and complete a current ECS operation and generate and send check result information after the error check and scrub ECS operation is performed on memory cells corresponding to all the storage addresses. The check result information includes an error count of a row with a largest quantity of errors, an address of a row with the largest quantity of errors, and a cumulative value of errors/cumulative value of rows with an error.

In some embodiments, the control circuit includes an ECS circuit, a recording circuit, a first register circuit, a second register circuit, and a start circuit, and the ECS circuit includes a command generation circuit and a counting circuit. The command generation circuit is configured to generate one ECS command signal by adopting one refresh command at an interval in the ECS operation cycle. The adopted refresh command is no longer adopted to perform a refreshing operation. The counting circuit is connected to the command generation circuit, and is configured to: count the ECS command signal, to generate an address count value, one address count value indicating one storage address; and generate the ECS finish flag signal when the address count value reaches a first preset value, and send the ECS finish flag signal to the recording circuit and the first register circuit. The recording circuit is connected to the counting circuit, and is configured to: store error information; and generate the check result information based on the error information when the ECS finish flag signal is received, and send the check result information to the first register circuit. The error information is updated in the ECS operation cycle based on the address count value corresponding to each ECS operation and a check result of a memory cell corresponding to the address count value. The first register circuit is connected to the counting circuit and the recording circuit, and is configured to: store the ECS finish flag signal and the check result information, and send the ECS finish flag signal and the check result information to the outside in response to a mode register read command received from the outside. The second register circuit is configured to store an ECS configuration parameter. The start circuit is connected to the second register circuit, and is configured to parse the ECS configuration parameter when the ECS start flag signal sent from the outside is received, to form an ECS start signal. The ECS circuit is connected to the start circuit, and is configured to: receive the ECS start signal, and control, based on the ECS start signal, the memory chip to enter a new ECS operation cycle.

In some embodiments, the command generation circuit includes a first command generation circuit and a second command generation circuit.

The first command generation circuit is connected to the start circuit, and is configured to: receive the refresh command, and generate one ECS command signal by adopting a next refresh command at an interval. The second command generation circuit is connected to the first command generation circuit, and is configured to: receive the ECS command signal, and generate an internal command signal based on the ECS command signal. The counting circuit is specifically configured to increase the address count value by one each time one internal command signal is received.

In some embodiments, the control circuit is further configured to: receive an interval adjustment signal, and adjust a time interval between two consecutive ECS command signals based on the interval adjustment signal.

In some embodiments, the first command generation circuit is specifically configured to: receive a preset and the refresh command and generate one ECS command signal by adopting a next refresh command when a first quantity of clock cycles of the preset clock signal pass. A clock cycle length of the preset clock signal is controlled by the interval adjustment signal, and/or the first quantity is controlled by the interval adjustment signal. Alternatively, the first command generation circuit is further configured to: receive the refresh command, and generate one ECS command signal by adopting a next refresh command at an interval of a second quantity of refresh commands. The second quantity is controlled by the interval adjustment signal.

In some embodiments, the counting circuit includes a column counting circuit, a row counting circuit, and a bank counting circuit, and the address count value includes a column count value, a row count value, and a bank count value. The column counting circuit is connected to the second command generation circuit, and is configured to: receive the internal command signal; count the internal command signal to generate the column count value; increase the column count value by one each time one internal command signal is received; and output one row counting signal and reset the column count value to zero when the column count value reaches a second preset value. The row counting circuit is connected to the column counting circuit, and is configured to: receive the row counting signal; count the row counting signal to generate the row count value; increase the row count value by one each time one row counting signal is received; and output one bank counting signal and reset the row count value to zero when the row count value reaches a third preset value. The bank counting circuit is connected to the row counting circuit, and is configured to: receive the bank counting signal; count the bank counting signal to generate the bank count value; increase the bank count value by one each time one bank counting signal is received; and output one ECS finish flag signal when the bank count value reaches a fourth preset value. The counting circuit is further configured to reset the address count value to zero after the memory chip receives the ECS start flag signal. The first preset value includes the second preset value, the third preset value, and the fourth preset value.

In some embodiments, the memory chip is further configured to receive first processing information or second processing information from the outside.

The first processing information indicates to skip a row corresponding to the address of the row with the largest quantity of errors when writing into the memory array is performed, and the second processing information indicates to perform redundancy repair processing on the row corresponding to the address of the row with the largest quantity of errors.

According to a third aspect, an embodiment of the present disclosure provides an error check and scrub method, applied to a storage system. The storage system includes a memory controller and a memory chip, and the method includes the steps as follows.

An ECS finish flag signal is generated and the ECS finish flag signal is sent to the memory controller after the memory chip completes a current error check and scrub ECS operation cycle. The memory controller generates an ECS start flag signal based on the ECS finish flag signal, and sends the ECS start flag signal to the memory chip, so that the memory chip enters a new ECS operation cycle.

In some embodiments, the memory chip performs one error check and scrub ECS operation on a memory cell corresponding to each storage address in the ECS operation cycle; and generates check result information and completes a current ECS operation after the error check and scrub ECS operation is performed on memory cells corresponding to all the storage addresses. The memory controller receives the check result information sent by the memory chip, and sends first processing information or second processing information to the memory chip based on the check result information. The check result information includes an error count of a row with a largest quantity of errors, an address of a row with the largest quantity of errors, and a cumulative value of errors/cumulative value of rows with an error, the first processing information indicates to skip a row corresponding to the address of the row with the largest quantity of errors when data is written, and the second processing information indicates to perform redundancy repair processing on the row corresponding to the address of the row with the largest quantity of errors.

In some embodiments, the method further includes the steps as follows. The memory controller generates an interval adjustment signal, and sends the interval adjustment signal to the memory chip, to adjust a time interval at which the memory chip performs two consecutive error check and scrub ECS operations.

### BRIEF DESCRIPTION OF DRAWINGS

FIG. 1 is a schematic diagram of a structure of a storage system according to an embodiment of the present disclosure;

FIG. 2 is a schematic diagram 1 of a partial structure of a storage system according to an embodiment of the present disclosure;

FIG. 3 is a schematic diagram 2 of a partial structure of a storage system according to an embodiment of the present disclosure;

FIG. 4 is a schematic diagram 3 of a partial structure of a storage system according to an embodiment of the present disclosure;

FIG. 5 is a schematic diagram 4 of a partial structure of a storage system according to an embodiment of the present disclosure;

FIG. 6 is a schematic diagram of a structure of another storage system according to an embodiment of the present disclosure;

FIG. 7 is a schematic diagram 5 of a partial structure of a storage system according to an embodiment of the present disclosure;

FIG. 8 is a schematic diagram of a structure of a memory chip according to an embodiment of the present disclosure;

FIG. 9 is a schematic diagram of a structure of a control circuit according to an embodiment of the present disclosure;

FIG. 10 is a schematic diagram of a structure of another memory chip according to an embodiment of the present disclosure;

FIG. 11 is a schematic flowchart of an error check and scrub method according to an embodiment of the present disclosure; and

FIG. 12 is a schematic diagram of a structure of an electronic device according to an embodiment of the present disclosure.

### DESCRIPTION OF EMBODIMENTS

The following clearly describes the technical solutions in the embodiments of the present disclosure with reference to the accompanying drawings in the embodiments of the present disclosure. It may be understood that a specific embodiment described herein is merely intended to explain the related application, but is not intended to limit this application. In addition, it should be further noted that for ease of description, only a part related to the related application is shown in the accompanying drawings.

Unless otherwise defined, all technical and scientific terms adopted in this specification have meanings the same as those commonly understood by a person skilled in the technical field of the present disclosure. The terms adopted in this specification are merely intended to describe the embodiments of the present disclosure, and are not intended to limit the present disclosure.

The following descriptions relate to “some embodiments” describing a subset of all possible embodiments. However, it may be understood that “some embodiments” may be the same or different subsets of all the possible embodiments, and may be combined with each other when there is no conflict.

It should be noted that the term “first/second/third” in the embodiments of the present disclosure is merely intended to distinguish between similar objects, and does not represent specific sorting for the objects. It may be understood that “first/second/third” may be interchanged for a specific sequence or order if allowed, so that the embodiments of the present disclosure described herein can be implemented in a sequence other than those shown or described herein.

Before the embodiments of the present disclosure are further described in detail, nouns and terms in the embodiments of the present disclosure are first described. The nouns and the terms in the embodiments of the present disclosure are applicable to the following explanations: dynamic random access memory (DRAM);
synchronous dynamic random access memory (SDRAM);
double data rate (DDR);
low power DDR (LPDDR);
fifth-generation DDR (DDR5);
error check and scrub (ECS); and
error per row counter (EpRC).

A DDR5 DRAM design is taken as an example. A required ECS command needs to be generated for the DRAM at an interval of a specific period of time, and all memory cells in the DRAM need to be accessed, to perform complete error check and scrub on the DRAM within 24 hours. To be specific, rows and columns (Col) in all banks (BA) in all bank groups (BG) are accessed. Counting needs to be performed on each column, each row, each BA, and each BG on which ECS detection is performed, to better perform an ECS operation. All addresses are also counted after all ECS operations are performed within 24 hours. Currently, a complete ECS operation is started and finished under internal control of the DRAM. In this case, an ECS operation cycle is fixed. Consequently, when an ECS-related function is performed in the DRAM, an ECS operation process and another processing policy cannot be adjusted and controlled in real time based on an actual ECS check result, and flexibility lacks. Therefore, how to better perform the ECS operation in the DRAM to control a related process of the ECS operation is a problem that needs to be resolved.

Based on this, the embodiments of the present disclosure provide a storage system, a memory chip, and an error check and scrub method. In the storage system, after an ECS operation is completed within 24 hours, completion information and detected error information of ECS are transferred to a memory controller through a mode register (MR). After the completion information and the error information of ECS are received, the memory controller resets an address counter, and continues a new ECS operation. In addition, when the memory controller receives information about an address with an error, the address may be skipped when a memory array is read and written, or repair is performed based on redundancy. In this design, a start time of an ECS operation cycle may be controlled by the memory controller. In addition, an execution cycle of ECS may be adjusted based on check result information of ECS.

The following describes the embodiments of the present disclosure in detail with reference to the accompanying drawings.

In an embodiment of the present disclosure, FIG. 1 shows structural composition of a storage system 10 according to an embodiment of the present disclosure. The storage system 10 includes a memory chip 20 and a memory controller 30.

The memory chip 20 includes a memory array 21, and is configured to: perform an error check and scrub ECS operation on the memory array 21; and generate an ECS finish flag signal (ECS Finish Flag) and send the ECS finish flag signal (ECS Finish Flag) to the memory controller 30 after a current ECS operation cycle is completed.

The memory controller 30 is connected to the memory chip 20, and is configured to: receive the ECS finish flag signal (ECS Finish Flag), generate an ECS start flag signal (ECS Start Flag) based on the ECS finish flag signal (ECS Finish Flag), and send the ECS start flag signal (ECS Start Flag) to the memory chip 20, so that the memory chip 20 enters a new ECS operation cycle based on the ECS start flag signal.

It should be noted that this embodiment of the present disclosure relates to an overall framework design of the ECS circuit in an integrated circuit design, and in particular, to a requirement for performing complete error check and scrub on a DRAM for at least one time every 24 hours in a DRAM DDR5 chip. An overall framework of the ECS circuit is adopted to generate an ECS command signal and some internal command signals. When operations such as a DRAM read/write operation and a refreshing operation are performed, the error check and scrub ECS operation is sequentially performed on all memory cells. The overall framework may be applied to a related circuit executing an ECS function in the DRAM DDR5 chip, but is not limited to this range. This design may be applied to another memory chip, and other internal command signal, timing control, and counting circuits.

It should be noted that in the storage system 10 in this embodiment of the present disclosure, after the ECS operation is completed for memory cells corresponding to all address counting value of the DRAM, the memory controller 30 receives an ECS finish flag signal sent by a mode register, and sends the ECS start flag signal generated by the memory controller 30 to the memory chip 20. A memory in the storage system 10 may be but is not limited to the DRAM, and may be an SDRAM, a DDR, or the like. In addition, in another analog circuit/digital circuit, the storage system provided in this design can be adopted to complete receiving and sending of another operation signal.

In some embodiments, the memory chip 20 is specifically configured to: generate multiple ECS command signals and perform one error check and scrub ECS operation on a memory cell corresponding to each storage address based on the ECS command signal in the ECS operation cycle; and complete the current ECS operation and generate check result information (Error Information) after the error check and scrub ECS operation is performed on memory cells corresponding to all the storage addresses.

The memory controller 30 is further configured to: receive the check result information, and perform a processing operation on the memory chip 20 based on the check result information.

The check result information includes an error count of a row with a largest quantity of errors, an address of a row with the largest quantity of errors, and a cumulative value of errors/cumulative value of rows with an error.

It should be noted that the check result information is a quantity of error codewords and information about an address of an error that occur in an ECS operation process. The error count of a row with a largest quantity of errors and the address of the row with the largest quantity of errors in the check result information may be recorded by an error per row counter (EpRC), and the cumulative value of errors/cumulative value of rows with an error may be recorded in real time by an error counter (EC).

It should be noted that the error counter (EC) has two working modes: a codeword counting mode and a row counting mode. The two working modes may be selected and switched based on a test mode. Specifically, the codeword counting mode is executed if the test mode is in a first state, to count an error codeword of the memory array 21; and the row counting mode is executed if the test mode is in a second state, to count a row in which at least one error codeword exists in the memory array 21. Herein, the first state may be logic 1 indicating a high level, and the second state may be logic 0 indicating a low level; or the first state may be logic 0 indicating a low level, and the second state may be logic 1 indicating a high level. This embodiment of the present disclosure sets no limitation. In an actual application, this may be set based on a requirement, to increase counting flexibility.

It should be further noted that the processing operation of the memory controller 30 may be performing redundancy repair processing on the check result information, or skipping the address next time a read/write operation is performed on the memory array 21, to protect data accuracy, and improve ECS check efficiency.

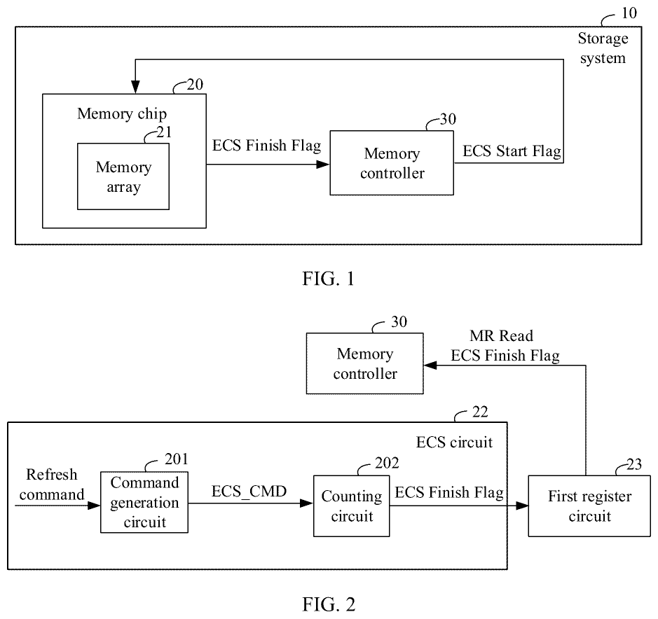

In some embodiments, as shown in FIG. 2, the memory chip 20 includes an ECS circuit 22 and a first register circuit 23, and the ECS circuit 22 includes a command generation circuit 201 and a counting circuit 202.

The command generation circuit 201 is configured to generate one ECS command signal (ECS_CMD) by adopting one refresh command at an interval in the ECS operation cycle. The adopted refresh command is no longer adopted to perform a refreshing operation.

The counting circuit 202 is connected to the command generation circuit 201, and is configured to: count the ECS command signal (ECS_CMD), to generate an address count value, one address count value indicating one storage address; and generate the ECS finish flag signal (ECS Finish Flag) when the address count value reaches a first preset value, and send the ECS finish flag signal (ECS Finish Flag) to the first register circuit 23.

The first register circuit (Mode Register) 23 is connected to the counting circuit 202, and is configured to: store the ECS finish flag signal (ECS Finish Flag), and send the ECS finish flag signal (ECS Finish Flag) to the memory controller 30 in response to a mode register read command (MR Read) received from the memory controller.

It should be noted that, as shown in FIG. 2, the ECS circuit 22 is configured to generate the ECS command signal (ECS_CMD). One ECS operation is correspondingly performed on the DRAM each time one ECS command signal (ECS_CMD) is generated. Herein, one ECS operation is performed on multiple memory cells corresponding to one storage address in the memory array 21. The ECS operation is configured to: determine whether a codeword error exists in multiple detected memory cells, and perform error correction when a codeword error is detected.

It should be further noted that in this embodiment of the present disclosure, the command generation circuit 201 may intercept a refresh command received at a next moment, and generate the ECS command signal (ECS_CMD) based on the refresh command. In addition, the corresponding intercepted refresh command disappears, to perform the ECS operation. In this way, the refreshing operation is not performed while the ECS operation is performed, to reduce power consumption of a memory during execution of ECS, and further avoid a memory fault caused when the refreshing operation is performed while the ECS operation is performed.

The counting circuit 202 further performs address counting based on an internal command signal when the ECS circuit 22 performs the ECS operation on the memory array 21 based on the internal command signal, to generate the ECS finish flag signal (ECS Finish Flag). Herein, the counting circuit 202 counts PRE as a clock signal. Specifically, the counting circuit 202 traverses column addresses (one row corresponds to multiple column addresses), then traverses row addresses, and finally traverses bank group addresses and bank addresses. In other words, the counting circuit 202 may separately perform counting on a column, a row, a bank, and a bank group of the memory array 21, and generate an ECS finish flag signal (ECS Finish Flag) when counting is completed (the address count value reaches the first preset value). It should be understood that each address count value includes four addresses: a bank group address, a bank address, a row address, and a column address.

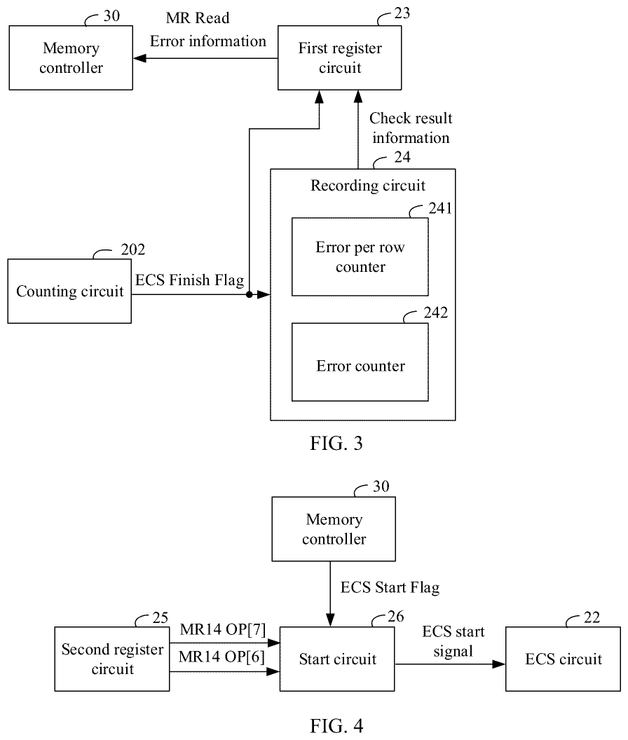

In some embodiments, as shown in FIG. 3, the memory chip 20 further includes a recording circuit (ECC Error Record) 24.

The recording circuit 24 is connected to the counting circuit 202, and is configured to: store error information; and generate the check result information (Error Information) based on the error information when the ECS finish flag signal (ECS Finish Flag) is received, and send the check result information (Error Information) to the first register circuit 23. The error information is updated in the ECS operation cycle based on an address count value corresponding to each ECS operation and a check result of a memory cell corresponding to the address count value.

The first register circuit 23 is connected to the recording circuit 24, and is further configured to: store the check result information (Error Information), and send the check result information (Error Information) to the memory controller 30.

It should be noted that, the counting circuit 202 generates an ECS finish flag signal (ECS Finish Flag) when counting is finished, and sends the ECS finish flag signal to the recording circuit 24. In addition, the counting circuit 202 further sends address information such as column address information, row address information, bank information, and bank group information to the recording circuit 24, so that the recording circuit 24 stores required address information.

It should be noted that, as shown in FIG. 3, the recording circuit 24 includes an error per row counter (EpRC) 241 and an error counter (EC) 242. The memory chip 20 records, through the error per row counter (EpRC) 241 and the error counter (EC) 242, error information (namely, the check result information) detected through each ECS operation, and sends the error information to the memory controller 30. The memory controller 30 performs a corresponding processing operation on the received check result information (Error Information).

For the error per row counter (EpRC) 241, the error per row counter (EpRC) 241 may count codeword errors in each row in the memory array 21, and store a quantity of codeword errors in a row with the largest quantity of codeword errors and address information of the row. Specifically, for example, error codewords in the ith row in the memory array 21 are counted. If the memory array 21 includes a total of M rows, and M is an integer greater than 0, i is an integer greater than 0 and less than or equal to M. When a row counting finish signal is received, it indicates that the ECS operation is completed for all storage bits in the ith row. In this case, counting of error information in the ith row may be finished, an obtained count value is an amount of error information (namely, a quantity of error codewords) in the ith row, and the obtained error count of a row with a largest quantity of errors and the address of the row with the largest quantity of errors are stored based on a row error threshold count (RETC). In this process, the error counter (EC) 242 is always working, and is configured to store the cumulative value of errors/cumulative value of rows with an error in the memory chip 20.

It should be further noted that, error counting starts to be performed on the 1st row, and a count value corresponding to the 1st row is adopted as a target count value and stored in the recording circuit 24 if at least one piece of error information exists in the 1st row; then, error counting continues to be performed on the 2nd row, an obtained count value is compared with the target count value stored in the recording circuit 24, and the target count value stored in the recording circuit 24 is cleared, and a count value corresponding to the 2nd row is adopted as a new target count value and stored in the recording circuit 24, if the count value corresponding to the 2nd row is greater than the target count value; . . . . In this way, error counting is sequentially performed. The target count value in the recording circuit 24 is replaced each time a larger count value appears. In this way, the target count value stored in the recording circuit 24 is a count value of a row with the largest amount of error information when the ECS finish flag signal (ECS Finish Flag) is received, and then the recording circuit 24 sends the stored check result information to the memory controller 30 through the first register circuit 23.

It may be understood that if no error information exists in the 1st row to the (i−1)th row, and error information does not appear until the ith row, no target count value in the ith row may be adopted for comparison, and a count value corresponding to the ith row is directly adopted as the target count value and stored in the first register circuit 23. Alternatively, the recording circuit 24 counts error information in the 1st row based on the stored error information and the ECS finish flag signal (ECS Finish Flag). A count value of the 1st row is stored as the target count value in the recording circuit 24 after the count value of the 1st row is determined. Counting continues to be performed on a target row in the foregoing manner after counting performed on the 1st row is finished. In this case, the target row represents a row other than the 1st row. In this case, the count value of the 1st row may be first stored in the recording circuit 24 even if the count value of the 1st row is 0. For the 2nd row, a corresponding count value is compared with 0, until a final target count value is determined.

It should be further noted that, in the ECS operation cycle, if a quantity that is of error codewords in an error row and that is stored in the recording circuit 24 reaches a preset threshold, the recording circuit 24 may send, to the memory controller 30 in real time without waiting for the ECS finish flag signal (ECS Finish Flag) sent by the counting circuit 202, information about row addresses in which a quantity of error codewords that reaches the preset threshold is located, so that the memory controller 30 can control, in a timely manner, to skip or repair these row addresses in a read/write operation; or may record information about addresses in which an error occurs and periodically send the information to the memory controller 30, so that the memory controller 30 can send a repair instruction in a timely manner, to repair the information about the addresses with the errors. In this way, repair efficiency of the storage system 10 is improved, and integrity and accuracy of data information can also be ensured.

In some embodiments, as shown in FIG. 4, the memory chip 20 further includes a second register circuit 25 and a start circuit 26.

The second register circuit 25 is configured to store an ECS configuration parameter.

The start circuit 26 is connected to the memory controller 30 and the second register circuit 25, and is configured to parse the ECS configuration parameter when the ECS start flag signal (ECS Start Flag) sent by the memory controller 30 is received, to generate an ECS start signal.

The ECS circuit 22 is connected to the start circuit 26, and is configured to: receive the ECS start signal, and control, based on the ECS start signal, the memory chip 20 to enter a new ECS operation cycle.

It should be noted that when the ECS start flag signal (ECS Start Flag) is received, the start circuit 26 decodes an ECS configuration parameter controlled by a first mode signal MR14 OP[6] and a second mode signal MR14 OP[7], to obtain an ECS start signal, so as to indicate the memory chip 30 to start a new ECS operation. If the start circuit 26 receives no ECS start flag signal (ECS Start Flag), the start circuit 26 neither performs a configuration parameter parsing operation nor sends an ECS start signal to the ECS circuit 22, and the memory chip 20 continues to execute work that is not completed in a current round. In this way, the memory controller 30 sends the ECS start flag signal (ECS Start Flag) to the start circuit 26 only after the memory chip 20 completes complete work for one time, to ensure that integrity of each operation cycle of the memory chip 20 is not affected, and stability of the storage system 10 is improved.

In some embodiments, the memory controller 30 is further configured to generate and send an interval adjustment signal based on the check result information.

The memory chip 20 is further configured to: receive the interval adjustment signal, and adjust a time interval between two consecutive ECS command signals (ECS_CMD) based on the interval adjustment signal.

It should be noted that, in the ECS operation cycle, the ECS command signal (ECS_CMD) may be generated based on different command signals to perform the ECS operation, and the ECS operation may be performed based on the refresh command and/or the ECS operation is performed based on the clock signal. In this case, the ECS circuit 22 may generate the ECS command signal (ECS_CMD) based on the refresh command and/or the clock signal, to perform the ECS operation, thereby simplifying a procedure required for generating the ECS operation, and improving flexibility of performing the ECS operation.

It should be noted that the command generation circuit 201 obtains the refresh command, and generates the ECS command signal (ECS_CMD) adopted to perform the ECS operation, each time a count value of the refresh command/clock signal meets a preset condition. If the ECS circuit 22 generates the ECS command signal (ECS_CMD) based on the refresh command, and the ECS circuit 22 previously obtains the refresh command at an interval of three refresh commands to generate an ECS command signal (ECS_CMD), the ECS circuit 22 may currently obtain one refresh command at an interval of four/five/six/seven . . . refresh commands through an adjustment function of the interval adjustment signal, to generate an ECS command signal (ECS_CMD). In this case, a quantity of refresh commands is controlled by the interval adjustment signal, to further adjust and control a generation frequency of the ECS command signal (ECS_CMD). If the ECS circuit 22 generates the ECS command signal (ECS_CMD) based on a cycle of the clock signal, and it is assumed that the ECS circuit 22 previously obtains the refresh command at an interval of two clock cycles to generate an ECS command signal (ECS_CMD), the ECS circuit 22 may currently obtain the refresh command at an interval of three/four/five/six . . . clock cycles through adjustment performed based on the interval adjustment signal, to generate an ECS command signal (ECS_CMD). In this case, a quantity of clock cycles may also be controlled by the interval adjustment signal, to further adjust a generation frequency of the ECS command signal (ECS_CMD). In conclusion, the memory controller controls the generation frequency of the ECS command signal (ECS_CMD) based on the interval adjustment signal in the ECS operation cycle, to control the ECS operation cycle, thereby meeting actual requirements of different circuits, better performing the ECS operation, and improving flexibility of the entire storage system 10.

It should be understood that the time interval is determined based on a specific circuit structure and function of the memory controller 30, and may be modified based on an actual requirement. It should be noted that a refresh command obtained in this case is a refresh command that appears after the count value meets the preset condition. Therefore, the refresh command obtained in this case is specifically a refresh command (or referred to as a next refresh command) that appears at a next moment. In this way, a time interval between ECS operations is planned based on whether the count value meets the preset condition, to ensure that complete error check and scrub is performed for one time within 24 hours.

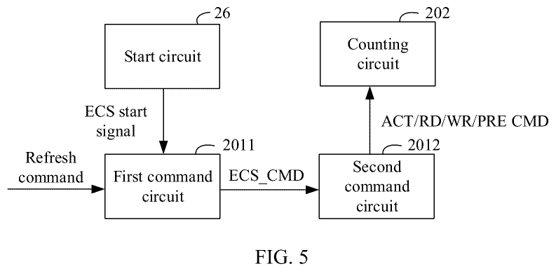

In some embodiments, as shown in FIG. 5, the command generation circuit 201 includes a first command generation circuit 2011 and a second command generation circuit 2012.

The first command generation circuit 2011 is connected to the start circuit 26, and is configured to: receive the refresh command, and generate one ECS command signal (ECS_CMD) by adopting a next refresh command at an interval.

The second command generation circuit 2012 is connected to the first command generation circuit, and is configured to: receive the ECS command signal, and generate an internal command signal based on the ECS command signal (ECS_CMD).

The counting circuit 202 is specifically configured to increase the address count value by one each time one internal command signal is received.

It should be noted that, as shown in FIG. 5, the ECS circuit (or referred to as an ECS system) 22 includes the first command generation circuit 2011 (or referred to as ECS_CMD GEN), the second command generation circuit (or referred to as INT_CMD) 2012, and the counting circuit (ADD_CNT) 202. The ECS circuit 22 generates the ECS command signal (ECS_CMD) at an interval of a specified period of time. The internal command signal may be independently generated internally by the memory chip 20 after the ECS command signal (ECS_CMD) is generated. The internal command signal may include an active command signal (active CMD, which is represented by ACT CMD in FIG. 5), a read command signal (read CMD, which is represented by RD CMD in FIG. 5), a write command signal (write CMD, which is represented by WR CMD in FIG. 5), and a precharge signal (precharge CMD, which is represented by PRE CMD in FIG. 5). A read-modify-write operation may be performed on a memory cell of a specified address in the DRAM based on ACT CMD, RD CMD, WR CMD, and PRE CMD. Specifically, the second command generation circuit 2012 sequentially generates an ACT command signal, an RD command signal, a WR command signal, and a PRE command signal based on a preset timing condition after the ECS command signal (ECS_CMD) is received. Timing control between internal command signals may be specifically implemented by a delay line.

When a complete ECS operation is completed, and the memory controller 30 receives the ECS finish flag signal (ECS Finish Flag) and the check result information (Error Information) generated by the recording circuit 24, the memory controller 30 may send the ECS start flag signal (ECS Start Flag) to control the memory chip 20 to start a new ECS operation, and needs to correspondingly process check result information (Error Information) detected through ECS.

In some embodiments, the first command generation circuit 2011 is specifically configured to: receive a preset clock signal and the refresh command and generate one ECS command signal (ECS_CMD) by adopting a next refresh command when a first quantity of clock cycles of the preset clock signal pass.

A clock cycle length of the preset clock signal is controlled by the interval adjustment signal, and/or the first quantity is controlled by the interval adjustment signal.

It should be noted that the preset clock signal may be a clock signal that is generated by an oscillator and has a fixed frequency. The clock cycle length is also adjustable because the interval adjustment signal is adjustable. For example, the first command generation circuit 2011 may intercept one refresh command at an interval of two clock cycles, or intercept one refresh command at an interval of three clock cycles, or intercept one refresh command at an interval of six clock cycles, . . . . In this way, a corresponding generation interval of the ECS command signal (ECS_CMD) also changes. In this way, a generation interval of an ECS command signal and the ECS operation cycle can be accurately controlled, and circuit timing requirements in a case of different ECS operation cycles (12 hours/24 hours/48 hours, or the like) can be met.

In some embodiments, the first command generation circuit 2011 is specifically configured to: receive the refresh command, and generate one ECS command signal by adopting a next refresh command at an interval of a second quantity of refresh commands.

The second quantity is controlled by the interval adjustment signal.

It should be noted that the first command generation circuit 2011 may further generate the ECS command signal (ECS_CMD) by controlling the quantity of refresh commands. For example, the first command generation circuit 2011 may intercept one refresh command at an interval of three refresh commands to generate an ECS command signal (ECS_CMD); or intercept one refresh command at an interval of five refresh commands to generate an ECS command signal (ECS_CMD); or intercept one refresh command at an interval of eight refresh commands to generate an ECS command signal (ECS_CMD), . . . . The quantity of refresh commands is controlled to control the generation interval of the ECS command signal (ECS_CMD), without a need to add a clock circuit and a related control circuit. A circuit structure is relatively simple, and circuit timing requirements in a case of different ECS operation cycles (12 hours/24 hours/48 hours, or the like) can be met.

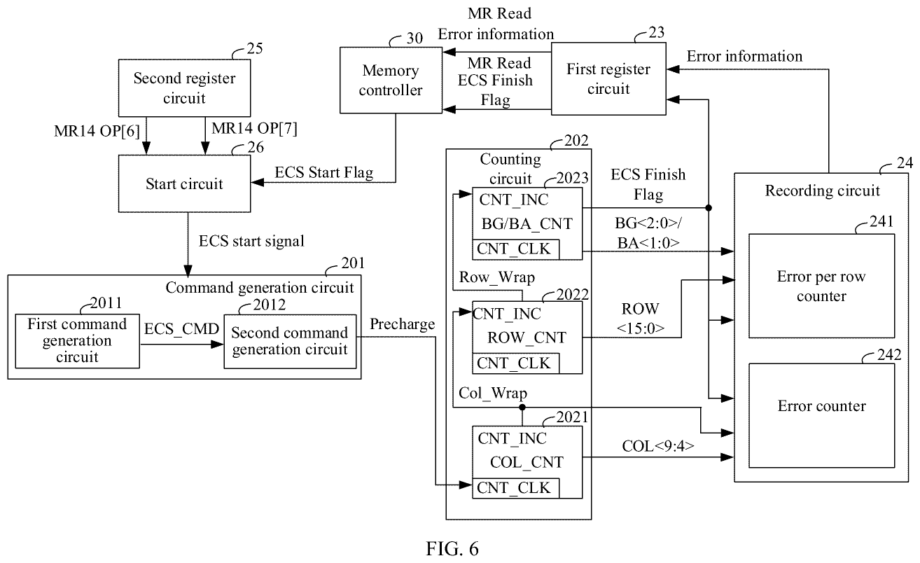

In some embodiments, as shown in FIG. 6, the counting circuit 202 includes a column counting circuit (COL_CNT) 2021, a row counting circuit (ROW_CNT) 2022, and a bank counting circuit (BG/BA_CNT) 2023, and the address count value includes a column count value COL<9:4>, a row count value ROW<15:0>, and a bank count value BG<2:0>/BA<1:0>.

The column counting circuit (COL_CNT) 2021 is connected to the second command generation circuit 2012, and is configured to: receive the internal command signal; count the internal command signal to generate the column count value COL<9:4>; increase the column count value COL<9:4> by one each time one internal command signal is received; and output one row counting signal (Col Wrap) and reset the column count value COL<9:4> to zero when the column count value COL<9:4> reaches a second preset value.

The row counting circuit (ROW_CNT) 2022 is connected to the column counting circuit 2021, and is configured to: receive the row counting signal (Col Wrap); count the row counting signal (Col Wrap) to generate the row count value ROW<15:0>; increase the row count value ROW<15:0> by one each time one row counting signal (Col Wrap) is received; and output one bank counting signal (Row_Wrap) and reset the row count value ROW<15:0> to zero when the row count value ROW<15:0> reaches a third preset value.

The bank counting circuit (BG/BA_CNT) 2023 is connected to the row counting circuit 2022, and is configured to: receive the bank counting signal (Row_Wrap); count the bank counting signal (Row_Wrap) to generate the bank count value BG<2:0>/BA<1:0>; increase the bank count value BG<2:0>/BA<1:0> by one each time one bank counting signal (Row_Wrap) is received; and output one ECS finish flag signal (ECS Finish Flag) when the bank count value BG<2:0>/BA<1:0> reaches a fourth preset value.

The first preset value includes the second preset value, the third preset value, and the fourth preset value.

It should be noted that the internal command signal received by the column counting circuit (COL_CNT) 2021 is PRE (Precharge in FIG. 6), and PRE is adopted as a clock signal for counting, because four commands of ACT CMD, RD CMD, WR CMD, and PRE CMD need to be sequentially executed for a complete ECS operation. PRE CMD is the last command, and therefore, may indicate that the ECS operation is finished. It should be understood that the address count value reaches the first preset value when the column count value reaches the second preset value, the row count value reaches the third preset value, and the bank count value reaches the fourth preset value. In this case, the counting circuit 202 outputs the ECS finish flag signal (ECS Finish Flag), indicating that the ECS operation is finished.

It should be noted that the ECS finish flag signal (ECS Finish Flag) includes a row counting signal indicating that counting is completed for each storage bit in one row, a bank counting signal indicating that counting is completed for each row in one BA, and an ECS finish flag signal (ECS Finish Flag) indicating that counting is completed for each BA in one BG and counting is completed for each BG in the memory array 21.

It should be noted that the bank counting circuit 2023 includes BA_CNT and BG_CNT. The bank counting circuit 2023 completes counting only when both BA_CNT and BG_CNT meet the fourth preset value. In this case, the bank counting circuit 2023 sends the generated ECS finish flag signal (ECS Finish Flag) to the memory controller 30. It should be understood that the fourth preset value herein includes two values: one is a value of the BA and the other is a value of the BG. In addition, the bank count value BG<2:0>/BA<1:0> is related to a quantity of BAs and a quantity of BGs. If an initial value of the bank count value BG<2:0>/BA<1:0> is 000 and 00, the memory array 21 includes four BGs, and each BG includes two BAs, when the bank count value BG<2:0>/BA<1:0> is 011 and 10, it indicates that counting is completed.

For ease of understanding, a working process of the counting circuit 202 is specifically described. It is assumed that the memory array 21 includes four BGs: BG0, BG1, BG2, and BG3, and each BG includes eight BAs: BA0, BA1, BA2, BA3, BA4, BA5, BA6, and BA7. In other words, counting is completed when the bank count value is 100 and 1000, and the ECS finish flag signal (ECS Finish Flag) is output. BA5 in the BG2 is taken as an example. BA5 includes four rows: Row0, Row1, Row2, and Row3, and BA5 includes four columns: Col0, Col1, Col2, and Col3. In each BG, each storage bit is denoted as Bitmn, m represents a row in which the storage bit is located in a BA, and n represents a column in which the storage bit is located in the BA. For example, Bit23 represents a storage bit located by Row2 and Col3 in the BA. A storage bit on which the ECS operation is currently being performed is denoted as a target storage bit, and a row, a BA, and a BG to which the target storage bit belongs are respectively recorded as a target row, a target bank, and a target bank group. For example, if the ECS operation is being performed on Bit31 in BA4 in BG2, the target row is Row3 in BA4 in BG2, the target bank is BA4 in BG2, and the target bank group is BG2. It should be understood that each ECS operation is performed on one storage bit in the memory array 21, and one address in the DRAM usually corresponds to multiple storage bits.

The column counting circuit (COL_CNT) 2021 may sequentially count storage bits included in each row in the memory array 21. In this way, in one complete ECS process for the memory array 21, the ECS operation is first sequentially performed on each storage bit in a first row Row0 in BA0 in BG0. When the ECS operation is performed on Bit00, a corresponding PRE signal is sent to a clock terminal (CNT_CLK represents a clock terminal of each counting circuit in FIG. 6) of the column counting circuit (COL_CNT) 2021, and a column count value of Row0 is increased by 1 each time one PRE signal is received. It may be understood that the column count value COL<9:4> represents a quantity of storage bits for which the ECS operation is completed in the target row. If Row0 includes four storage bits, when the column count value of Row0 is 4 (the second preset value), it indicates that column counting is completed for Row0. In this case, the column counting circuit (COL_CNT) 2021 generates a column count value COL<9:4> and a row counting signal (Col Wrap). The row counting signal (Col Wrap) is sent to the row counting circuit (ROW_CNT) 2022, and the column count value COL<9:4> is sent to the recording circuit 24. The column counting circuit (COL_CNT) 2021 resets the count value to zero after column counting is completed for Row0, then continues to perform column counting on Row1, and sequentially performs counting on each row in the memory array 21 based on this procedure, until column counting is completed for each row in the memory array 21. In other words, the column counting circuit (COL_CNT) 2021 is further configured to continue to perform column counting on a next target row after the column count value COL<9:4> and the row counting signal (Col Wrap) are generated, until column counting is completed for each row in the memory array 21.

The row counting circuit (ROW_CNT) 2022 performs counting based on the row counting signal (Col Wrap). Specifically, the column counting circuit (COL_CNT) 2021 generates a row counting signal (Col Wrap) and sends the row counting signal (Col Wrap) to the row counting circuit (ROW_CNT) 2022 after counting is completed for Row0. The row count value ROW<15:0> of the target bank on which the row counting circuit (ROW_CNT) 2022 performs counting is increased by 1. It may be understood that the row count value ROW<15:0> represents a quantity of rows for which the ECS operation is completed in the target bank. The column counting circuit (COL_CNT) 2021 sends another row counting signal (Col Wrap) to the row counting circuit (ROW_CNT) 2022 after counting is completed for Row1, and the row count value of the target bank continues to be increased by 1, . . . . Assuming that BA0 includes four rows, when the row count value of the target bank is 4 (the third preset value), it indicates that row counting is completed for BA0. In this case, the row counting circuit (ROW_CNT) 2022 generates the bank counting signal (Row_Wrap) and the row count value Row<15:0>. The bank counting signal (Row_Wrap) is sent to the bank counting circuit (BG/BA_CNT) 2023, and the row count value Row<15:0> is sent to the recording circuit 24. The row counting circuit (ROW_CNT) 2022 resets the count value to zero after row counting is completed for BA0, then continues to perform row counting on BA1, and sequentially performs counting on each BA in the memory array 21 based on this procedure, until counting is completed for each BA in the memory array 21. In other words, the row counting circuit (ROW_CNT) 2022 is further configured to continue to perform row counting on a next target bank after the bank counting signal (Row_Wrap) and the row count value Row<15:0> are generated, until row counting is completed for each BA in the memory array 21.

The bank counting circuit (BG/BA_CNT) 2023 performs counting based on the bank counting signal (Row_Wrap). BG0 is still taken as an example. The row counting circuit (ROW_CNT) 2022 generates one bank counting signal (Row_Wrap) and sends the bank counting signal to the bank counting circuit (BG/BA_CNT) 2023 after counting is completed for BA0. The bank count value of the target bank group on which the bank counting circuit (BG/BA_CNT) 2023 performs counting is increased by 1. It may be understood that the bank count value BG<2:0>/BA<1:0> represents a quantity of BAs/BGs for which the ECS operation is completed in the target bank group. The row counting circuit (ROW_CNT) 2022 generates another bank counting signal (Row_Wrap) after counting is completed for BA1, and sends the bank counting signal to the bank counting circuit (BG/BA_CNT) 2023. The bank count value of the target bank group continues to be increased by 1, . . . . If BG0 includes six BAs, when the bank count value of the target bank group is 6 (the fourth preset value), it indicates that bank counting is completed for BG0. In this case, the bank counting circuit (BG/BA_CNT) 2023 sends the generated ECS finish flag signal (ECS Finish Flag) and the bank count value BG<2:0>/BA<1:0> to the recording circuit 24. The bank counting circuit (BG/BA_CNT) 2023 resets the count value to zero after BA counting is completed for BG0, then continues to perform row counting on BG1, and sequentially performs counting on each BG in the memory array 21 based on this procedure, until counting is completed for each BG in the memory array 21. It should be understood that numbers in this embodiment of the present disclosure are merely examples, and constitute no related limitation.

In other words, a main function of the counting circuit 202 is as follows: Rows and columns in all BAs in all BGs need to be accessed, to perform complete error check and scrub on the DRAM. For each ECS operation, the counting circuit 202 increases a count of column addresses (namely, a column count of a target row) after each internal PRE command signal. A count of row addresses (namely, a row count of a target bank) starts to be increased after all column addresses in the target row are counted, until all codewords in each row in a bank are accessed. Then, a count of banks (namely, a BA count of a target bank group) starts to be increased. A process of accessing a codeword in a previous BA is repeated. A count of a BG starts to be increased when counting is completed for all BAs in a BG, until all BAs of the DRAM are accessed. In this case, one complete error check and scrub operation is completed.

In some embodiments, the counting circuit 202 is further configured to reset the address count value to zero after the memory chip 20 receives the ECS start flag signal (ECS Start Flag).

It should be noted that when the memory controller 30 receives the ECS finish flag signal (ECS Finish Flag) and the check result information (Error Information), the start circuit 26 parses, based on the ECS start flag signal (ECS Start Flag) sent by the memory controller 30, the ECS configuration parameter stored in the second register circuit 25, and outputs an ECS start signal to the memory chip 20. The ECS start signal indicates the memory chip 20 to reset the address count value to zero, so that the memory chip 20 starts a new ECS operation.

It should be further noted that a circuit performing a counting function in this embodiment of the present disclosure may be implemented by a synchronous counter, or may be implemented by an asynchronous counter. This is not specifically limited herein.

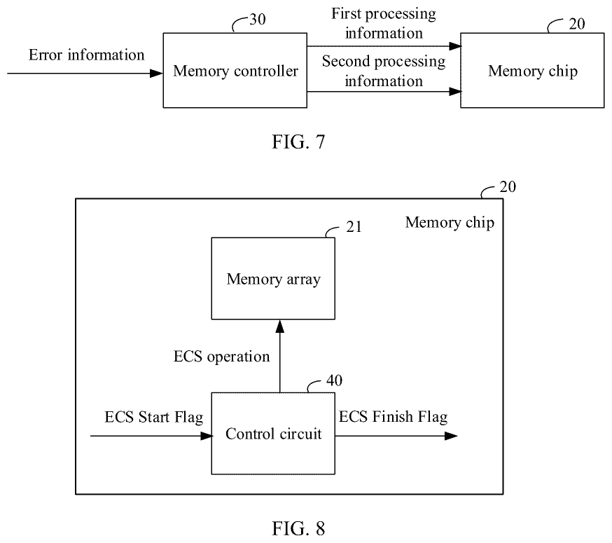

In some embodiments, as shown in FIG. 7, the memory controller 30 is further configured to send first processing information to the memory chip 20 when the check result information (Error Information) is received.

The first processing information indicates to skip a row corresponding to an address of a row with the largest quantity of errors when writing into the memory array 21 is performed.

It should be noted that the recording circuit 24 records the error information of the memory array 21, and sends the check result information (Error Information) to the memory controller 30 to perform a corresponding operation. When writing into the memory array 21 is performed, the memory controller 30 identifies the error information, and skips the error information, to avoid adopting error data, and improve data storage accuracy.

In some embodiments, as shown in FIG. 7, the memory controller 30 is further configured to send second processing information to the memory chip 20 when the check result information (Error Information) is received.

The second processing information indicates to perform redundancy repair processing on the row corresponding to the address of the row with the largest quantity of errors.

It should be noted that the DRAM includes multiple banks, each bank is further divided into multiple sections, and each section includes multiple normal word lines and multiple redundant word lines. When a normal word line has an error or becomes invalid, the redundant word line replaces the normal word line that has an error or becomes invalid. This process is the foregoing redundancy repair processing. Redundancy repair processing is performed on the row corresponding to the address of the row with the largest quantity of errors, to improve data integrity, and further improve storage stability.

It should be further noted that because the check result information (Error Information) is continuously updated in the ECS operation cycle, the memory controller 30 may receive, periodically or in real time based on a mode register read command, the check result information (Error Information) sent by the recording circuit 24. Therefore, a row error threshold count may be set. A codeword error per row count is compared with the row error threshold count to generate comparison results in different states, and the memory controller 30 performs a corresponding processing operation based on different states of the comparison results. Specifically, the row error threshold count includes a first threshold and a second threshold, and the second threshold is greater than the first threshold. If a quantity of error codewords of a specific row is less than the first threshold, a comparison result is in a first state, the memory controller 30 sends no processing information to the memory chip 20, and the memory chip 20 performs work the same as previous work. If a quantity of error codewords of a specific row is greater than the first threshold and is less than the second threshold, a comparison result is in a second state, and the memory controller 30 sends the second processing information to the memory chip 20, to indicate the memory chip 20 to perform redundancy repair processing on the row corresponding to the row address. If a quantity of error codewords of a specific row is greater than the second threshold, a comparison result is in a third state, and the memory controller 30 sends the first processing information to the memory chip 20, to indicate the memory chip 20 to skip a row corresponding to the address when writing into the memory array 21 is performed. The row error threshold count is set, so that processing information of the memory controller 30 can be more accurate, and the memory chip 20 can process the row corresponding to the address of the row with the largest quantity of errors in a more timely manner.

It should be understood that the first threshold and the second threshold herein may be set based on an actual application scenario and performance of the memory chip 20. For example, the first threshold is 1, and the second threshold is 4. The memory controller 30 sends no processing information, and the memory chip 20 works normally, when a quantity of error codewords in a specific row is less than 1. The memory controller 30 sends the second processing information to the memory chip 20 when a quantity of error codewords in a specific row is greater than 1 and is less than 4. The memory controller 30 sends the first processing information to the memory chip 20 when a quantity of error codewords in a specific row is greater than 4. In addition, when quantities of error codewords of multiple rows in the memory array 21 exceed a row error threshold count, the memory controller 30 continuously sends corresponding processing information to the memory chip 20, and the memory chip 20 also continuously repairs error rows, to improve repair efficiency and detection costs. Certainly, a sequence of the first processing information and the second processing information may be changed, and is not limited herein.

Further, an error row threshold may be further set. If the cumulative value of rows with an error is less than the error row threshold, the memory controller 30 may choose to send the first processing information or the second processing information to the memory chip 20, and perform a corresponding operation. If the cumulative value of rows with an error is greater than the error row threshold, that is, too many rows in the memory array 21 become invalid, there may not be enough redundant rows for adoption, or the memory chip 20 cannot perform a related function well. In this case, the memory controller 30 sends a finish signal to the memory chip 20, to indicate the memory chip 20 to stop working, and the memory chip 20 may be replaced.

In another embodiment of the present disclosure, FIG. 8 shows structural composition of a memory chip 20 according to an embodiment of the present disclosure. The memory chip 20 includes a memory array 21 and a control circuit 40, and the memory array 21 is connected to the control circuit 40.

The control circuit 40 is configured to: perform an error check and scrub ECS operation on the memory array 21; and generate an ECS finish flag signal (ECS Finish Flag) and send the ECS finish flag signal (ECS Finish Flag) to the outside after a current ECS operation cycle is completed; and receive an ECS start flag signal (ECS Start Flag) from the outside, and enter a new ECS operation cycle based on the ECS start flag signal (ECS Start Flag).

In some embodiments, the control circuit 40 is specifically configured to: generate multiple ECS command signals (ECS_CMD) and perform one error check and scrub ECS operation on a memory cell corresponding to each storage address based on the ECS command signal (ECS_CMD) in the ECS operation cycle; and complete the current ECS operation and generate and send check result information (Error Information) after the error check and scrub ECS operation is performed on memory cells corresponding to all the storage addresses.

The check result information (Error Information) includes an error count of a row with a largest quantity of errors, an address of a row with the largest quantity of errors, and a cumulative value of errors/cumulative value of rows with an error.

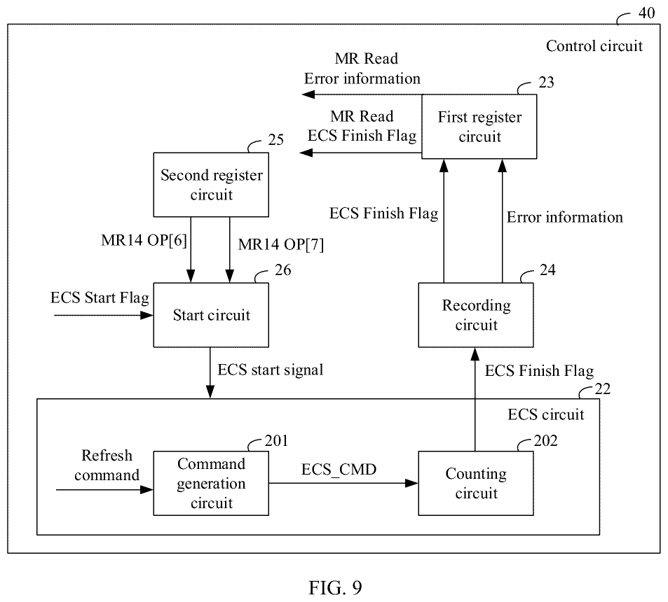

In some embodiments, as shown in FIG. 9, the control circuit 40 includes an ECS circuit 22, a recording circuit 24, a first register circuit 23, a second register circuit 25, and a start circuit 26, and the ECS circuit 22 includes a command generation circuit 201 and a counting circuit 202.

The command generation circuit 201 is configured to generate one ECS command signal (ECS_CMD) by adopting one refresh command at an interval in the ECS operation cycle. The adopted refresh command is no longer adopted to perform a refreshing operation.

The counting circuit 202 is connected to the command generation circuit 201, and is configured to: count the ECS command signal (ECS_CMD), to generate an address count value, one address count value indicating one storage address; and generate the ECS finish flag signal (ECS Finish Flag) when the address count value reaches a first preset value, and send the ECS finish flag signal (ECS Finish Flag) to the recording circuit 24 and the first register circuit 23.

The recording circuit 24 is connected to the counting circuit 202, and is configured to: store error information; and generate the check result information (Error Information) based on the error information when the ECS finish flag signal (ECS Finish Flag) is received, and send the check result information (Error Information) to the first register circuit 23. The error information is updated in the ECS operation cycle based on an address count value corresponding to each ECS operation and a check result of a memory cell corresponding to the address count value.

The first register circuit 23 is connected to the counting circuit 202 and the recording circuit 24, and is configured to: store the ECS finish flag signal (ECS Finish Flag) and the check result information (Error Information), and send the ECS finish flag signal (ECS Finish Flag) and the check result information (Error Information) to the outside in response to a mode register read command received from the outside.

The second register circuit 25 is configured to store an ECS configuration parameter.

The start circuit 26 is connected to the second register circuit 25, and is configured to parse the ECS configuration parameter when the ECS start flag signal (ECS Start Flag) sent from the outside is received, to generate an ECS start signal

The ECS circuit 22 is connected to the start circuit 26, and is configured to: receive the ECS start signal, and control, based on the ECS start signal, the memory chip to enter a new ECS operation cycle.

The second register circuit 25 may directly send the stored ECS configuration parameter to the start circuit 26, or may send the ECS configuration parameter to the start circuit 26 in response to an external command.

In some embodiments, as shown in FIG. 5, the command generation circuit 201 includes a first command generation circuit 2011 and a second command generation circuit 2012.

The first command generation circuit 2011 is connected to the start circuit 26, and is configured to: receive the refresh command, and generate one ECS command signal (ECS_CMD) by adopting a next refresh command at an interval.

The second command generation circuit 2012 is connected to the first command generation circuit 2011, and is configured to: receive the ECS command signal (ECS_CMD), and generate an internal command signal (ACT/RD/WR/PRE CMD) based on the ECS command signal (ECS_CMD).

The counting circuit 202 is specifically configured to increase the address count value by one each time one internal command signal is received.

In some embodiments, the control circuit 40 is further configured to: receive the interval adjustment signal, and adjust a time interval between two consecutive ECS command signals (ECS_CMD) based on the interval adjustment signal.

In some embodiments, the first command generation circuit 2011 is specifically configured to: receive a preset clock signal and the refresh command and generate one ECS command signal (ECS_CMD) by adopting a next refresh command when a first quantity of clock cycles of the preset clock signal pass. A clock cycle length of the preset clock signal is controlled by the interval adjustment signal, and/or the first quantity is controlled by the interval adjustment signal.

Alternatively, the first command generation circuit 2011 is further configured to: receive the refresh command, and generate one ECS command signal (ECS_CMD) by adopting a next refresh command at an interval of a second quantity of refresh commands. The second quantity is controlled by the interval adjustment signal.

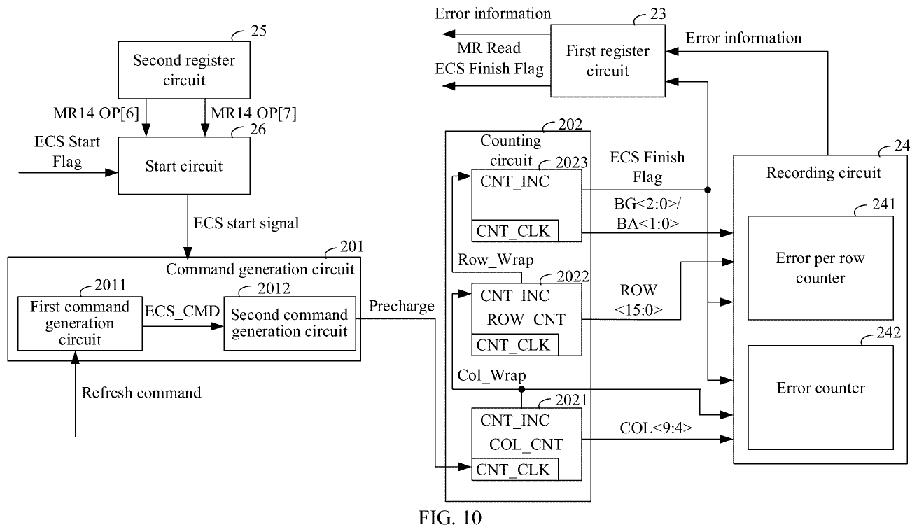

In some embodiments, as shown in FIG. 10, the counting circuit 202 includes a column counting circuit 2021, a row counting circuit 2022, and a bank counting circuit 2023, and the address count value includes a column count value COL<9:4>, a row count value ROW<15:0>, and a bank count value BG<2:0>/BA<1:0>.

The column counting circuit 2021 is connected to the second command generation circuit 2012, and is configured to: receive the internal command signal; count the internal command signal to generate the column count value COL<9:4>; increase the column count value COL<9:4> by one each time one internal command signal is received; and output one row counting signal (Col Wrap) and reset the column count value COL<9:4> to zero when the column count value COL<9:4> reaches a second preset value.

The row counting circuit 2022 is connected to the column counting circuit 2021, and is configured to: receive the row counting signal (Col Wrap); count the row counting signal (Col Wrap) to generate the row count value ROW<15:0>; increase the row count value ROW<15:0> by one each time one row counting signal (Col Wrap) is received; and output one bank counting signal (Row_Wrap) and reset the row count value ROW<15:0> to zero when the row count value ROW<15:0> reaches a third preset value.

The bank counting circuit 2023 is connected to the row counting circuit 2022, and is configured to: receive the bank counting signal (Row_Wrap); count the bank counting signal (Row_Wrap) to generate the bank count value BG<2:0>/BA<1:0>; increase the bank count value BG<2:0>/BA<1:0> by one each time one bank counting signal (Row_Wrap) is received; and output one ECS finish flag signal (ECS Finish Flag) when the bank count value BG<2:0>/BA<1:0> reaches a fourth preset value.

The counting circuit 202 is further configured to reset the address count value to zero after the memory chip 20 receives the ECS start flag signal (ECS Start Flag).

The first preset value includes the second preset value, the third preset value, and the fourth preset value.

In some embodiments, the memory chip 20 is further configured to receive first processing information or second processing information from the outside.

The first processing information indicates to skip a row corresponding to the address of the row with the largest quantity of errors when writing into the memory array is performed, and the second processing information indicates to perform redundancy repair processing on the row corresponding to the address of the row with the largest quantity of errors.

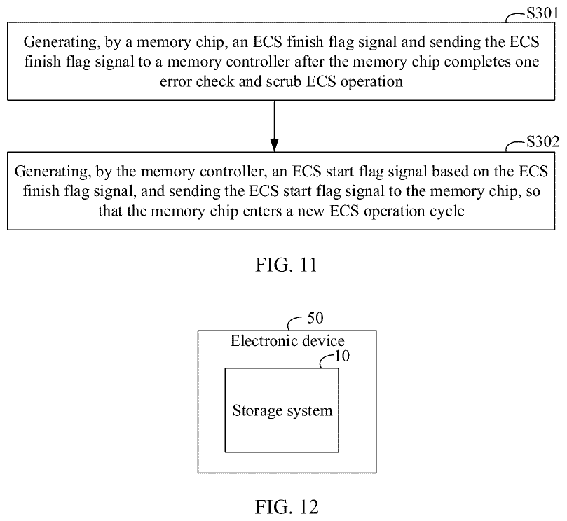

In another embodiment of the present disclosure, FIG. 11 shows an error check and scrub method. The method is applied to a storage system, and the storage system includes a memory controller and a memory chip. The method includes the steps as follows.

In the step of S301, an ECS finish flag signal is generated and the ECS finish flag signal is sent to the memory controller after the memory chip completes a current error check and scrub ECS operation cycle.

In the step of S302, the memory controller generates an ECS start flag signal based on the ECS finish flag signal, and sends the ECS start flag signal to the memory chip, so that the memory chip enters a new ECS operation cycle.

It should be noted that the ECS method provided in this embodiment of the present disclosure is applied to the storage system provided in the foregoing embodiment. For details not disclosed in this embodiment of the present disclosure, refer to the descriptions of the foregoing embodiment for understanding.

In some embodiments, the memory chip performs one error check and scrub ECS operation on a memory cell corresponding to each storage address in the ECS operation cycle; and generates check result information and completes a current ECS operation after the error check and scrub ECS operation is performed on memory cells corresponding to all the storage addresses.

The memory controller receives the check result information sent by the memory chip, and sends first processing information or second processing information to the memory chip based on the check result information.

The check result information includes an error count of a row with a largest quantity of errors, an address of a row with the largest quantity of errors, and a cumulative value of errors/cumulative value of rows with an error, the first processing information indicates to skip a row corresponding to the address of the row with the largest quantity of errors when data is written, and the second processing information indicates to perform redundancy repair processing on the row corresponding to the address of the row with the largest quantity of errors.

It should be noted that the memory controller may selectively send the first processing information or the second processing information to the memory chip based on the check result information. For a memory chip that may be repaired based on redundancy, the memory chip may be preferentially replaced based on redundancy. For a memory chip that has too many errors and that cannot be repaired based on redundancy, the address may be directly skipped when data is read, to ensure that another normal address can be accurately read. A sequence of the first processing information and the second processing information is not essentially limited, and is specifically determined based on a damage degree of data.

In some embodiments, the method further includes the step as follows.

The memory controller generates an interval adjustment signal, and sends the interval adjustment signal to the memory chip, to adjust a time interval at which the memory chip performs two consecutive error check and scrub ECS operations.

It should be noted that the interval adjustment signal may be adopted to control a generation frequency of an ECS command signal, to more flexibly perform the ECS operation, and improve error detection efficiency of ECS.

In another embodiment of the present disclosure, FIG. 12 is a schematic diagram of structural composition of an electronic device 50 according to an embodiment of the present disclosure. As shown in FIG. 12, the electronic device 50 may include the foregoing storage system 10.

The foregoing is merely preferred embodiments of the present disclosure, and is not intended to limit the protection scope of the present disclosure.

It should be noted that in the present disclosure, the terms “include”, “comprise”, or any other variant thereof are intended to cover non-exclusive inclusion, so that a process, method, article, or apparatus that includes a series of elements includes not only those elements but also other elements that are not expressly listed, or further includes elements inherent to such a process, method, article, or apparatus. An element preceded by “includes a . . . ” does not, without more constraints, preclude the presence of additional identical elements in the process, method, article, or apparatus that includes the element.

The sequence numbers of the foregoing embodiments of the present disclosure are merely for the purpose of description, and are not intended to indicate priorities of the embodiments.

The methods disclosed in the several method embodiments provided in the present disclosure may be randomly combined when there is no conflict, to obtain new method embodiments.

The features disclosed in the several product embodiments provided in the present disclosure may be randomly combined when there is no conflict, to obtain new product embodiments.

The features disclosed in the several method or device embodiments provided in the present disclosure may be randomly combined when there is no conflict, to obtain new method embodiments or new device embodiments.

The foregoing is merely specific implementations of the present disclosure, but is not intended to limit the protection scope of the present disclosure. Any variation or replacement readily figured out by a person skilled in the art within the technical scope disclosed in the present disclosure shall fall within the protection scope of the present disclosure. Therefore, the protection scope of the present disclosure shall be subject to the protection scope of the claims.

What is claimed is:

1. A storage system, the storage system comprising a memory chip and a memory controller;
the memory chip comprising a memory array, and being configured to: perform an error check and scrub ECS operation on the memory array; and generate an ECS finish flag signal and send the ECS finish flag signal to the memory controller after a current ECS operation cycle is completed; and
the memory controller being connected to the memory chip, and being configured to: receive the ECS finish flag signal, generate an ECS start flag signal based on the ECS finish flag signal, and send the ECS start flag signal to the memory chip, so that the memory chip enters a new ECS operation cycle based on the ECS start flag signal.

2. The storage system according to claim 1, wherein
the memory chip is specifically configured to: generate a plurality of ECS command signals and perform one error check and scrub ECS operation on a memory cell corresponding to each storage address based on the ECS command signal in the ECS operation cycle; and complete the current ECS operation and generate check result information after the error check and scrub ECS operation is performed on memory cells corresponding to all the storage addresses; and
the memory controller is further configured to: receive the check result information, and perform a processing operation on the memory chip based on the check result information, wherein
the check result information comprises an error count of a row with a largest quantity of errors, an address of a row with a largest quantity of errors, and a cumulative value of errors/cumulative value of rows with an error.

3. The storage system according to claim 2, wherein the memory chip comprises an ECS circuit, a first register circuit, and a recording circuit, and the ECS circuit comprises a command generation circuit and a counting circuit;
the command generation circuit is configured to generate one ECS command signal by adopting one refresh command at an interval in the ECS operation cycle, the adopted refresh command being not adopted to perform a refreshing operation;
the counting circuit is connected to the command generation circuit, and is configured to: count the ECS command signal, to generate an address count value, one address count value indicating one storage address; and generate the ECS finish flag signal when the address count value reaches a first preset value, and send the ECS finish flag signal to the first register circuit;
the first register circuit is connected to the counting circuit, and is configured to: store the ECS finish flag signal, and send the ECS finish flag signal to the memory controller in response to a mode register read command received from the memory controller;
the recording circuit is connected to the counting circuit, and is configured to: store error information; and generate the check result information based on the error information when the ECS finish flag signal is received, and send the check result information to the first register circuit, the error information being updated in the ECS operation cycle based on the address count value corresponding to each ECS operation and a check result of a memory cell corresponding to the address count value; and
the first register circuit is connected to the recording circuit, and is further configured to: store the check result information, and send the check result information to the memory controller.

4. The storage system according to claim 3, wherein the memory chip further comprises a second register circuit and a start circuit;
the second register circuit is configured to store an ECS configuration parameter;
the start circuit is connected to the memory controller and the second register circuit, and is configured to parse the ECS configuration parameter when the ECS start flag signal sent by the memory controller is received, to generate an ECS start signal; and
the ECS circuit is connected to the start circuit, and is configured to: receive the ECS start signal, and control, based on the ECS start signal, the memory chip to enter a new ECS operation cycle.

5. The storage system according to claim 4, wherein
the memory controller is further configured to generate and send an interval adjustment signal based on the check result information; and
the memory chip is further configured to: receive the interval adjustment signal, and adjust a time interval between two consecutive ECS command signals based on the interval adjustment signal.

6. The storage system according to claim 5, wherein the command generation circuit comprises a first command generation circuit and a second command generation circuit;
the first command generation circuit is connected to the start circuit, and is configured to: receive the refresh command, and generate one ECS command signal by adopting a next refresh command at an interval;
the second command generation circuit is connected to the first command generation circuit, and is configured to: receive the ECS command signal, and generate an internal command signal based on the ECS command signal; and
the counting circuit is specifically configured to increase the address count value by one each time one internal command signal is received.

7. The storage system according to claim 6, wherein
the first command generation circuit is specifically configured to: receive a preset clock signal and the refresh command and generate one ECS command signal by adopting a next refresh command when a first quantity of clock cycles of the preset clock signal pass, a clock cycle length of the preset clock signal being controlled by the interval adjustment signal, and/or the first quantity being controlled by the interval adjustment signal; or
the first command generation circuit is specifically configured to: receive the refresh command, and generate one ECS command signal by adopting a next refresh command at an interval of a second quantity of refresh commands, the second quantity being controlled by the interval adjustment signal.

8. The storage system according to claim 6, wherein the counting circuit comprises a column counting circuit, a row counting circuit, and a bank counting circuit, and the address count value comprises a column count value, a row count value, and a bank count value;
the column counting circuit is connected to the second command generation circuit, and is configured to: receive the internal command signal; count the internal command signal to generate the column count value; increase the column count value by one each time one internal command signal is received; and output one row counting signal and reset the column count value to zero when the column count value reaches a second preset value;
the row counting circuit is connected to the column counting circuit, and is configured to: receive the row counting signal; count the row counting signal to generate the row count value; increase the row count value by one each time one row counting signal is received; and output one bank counting signal and reset the row count value to zero when the row count value reaches a third preset value;
the bank counting circuit is connected to the row counting circuit, and is configured to: receive the bank counting signal; count the bank counting signal to generate the bank count value; increase the bank count value by one each time one bank counting signal is received; and output one ECS finish flag signal when the bank count value reaches a fourth preset value; and
the counting circuit is further configured to reset the address count value to zero after the memory chip receives the ECS start flag signal, wherein
the first preset value comprises the second preset value, the third preset value, and the fourth preset value.

9. The storage system according to claim 2, wherein
the memory controller is further configured to send first processing information and/or second processing information to the memory chip when the check result information is received, wherein
the first processing information indicates to skip a row corresponding to the address of the row with the largest quantity of errors when writing into the memory array is performed, and the second processing information indicates to perform redundancy repair processing on the row corresponding to the address of the row with the largest quantity of errors.

10. A memory chip, the memory chip comprising a memory array and a control circuit, and the memory array being connected to the control circuit;
the control circuit being configured to: perform an error check and scrub ECS operation on the memory array; and generate an ECS finish flag signal and send the ECS finish flag signal to an outside after a current ECS operation cycle is completed; and
receive an ECS start flag signal from the outside, and enter a new ECS operation cycle based on the ECS start flag signal.

11. The memory chip according to claim 10, wherein
the control circuit is specifically configured to: generate a plurality of ECS command signals and perform an error check and scrub ECS operation on a memory cell corresponding to each storage address based on the ECS command signal in the ECS operation cycle; and complete a current ECS operation and generate and send check result information after the error check and scrub ECS operation is performed on memory cells corresponding to all the storage addresses, the check result information comprising an error count of a row with a largest quantity of errors, an address of a row with a largest quantity of errors, and a cumulative value of errors/cumulative value of rows with an error; and
the memory chip is further configured to receive first processing information or second processing information from the outside after the check result information is sent, the first processing information indicating to skip a row corresponding to the address of the row with the largest quantity of errors when writing into the memory array is performed, and the second processing information indicating to perform redundancy repair processing on the row corresponding to the address of the row with the largest quantity of errors.

12. The memory chip according to claim 11, wherein the control circuit comprises an ECS circuit, a recording circuit, a first register circuit, a second register circuit, and a start circuit, and the ECS circuit comprises a command generation circuit and a counting circuit;
the command generation circuit is configured to generate one ECS command signal by adopting one refresh command at an interval in the ECS operation cycle, the adopted refresh command being no longer adopted to perform a refreshing operation;
the counting circuit is connected to the command generation circuit, and is configured to: count the ECS command signal, to generate an address count value, one address count value indicating one storage address; and generate the ECS finish flag signal when the address count value reaches a first preset value, and send the ECS finish flag signal to the recording circuit and the first register circuit;
the recording circuit is connected to the counting circuit, and is configured to: store error information; and generate the check result information based on the error information when the ECS finish flag signal is received, and send the check result information to the first register circuit, the error information being updated in the ECS operation cycle based on the address count value corresponding to each ECS operation and a check result of a memory cell corresponding to the address count value;
the first register circuit is connected to the counting circuit and the recording circuit, and is configured to: store the ECS finish flag signal and the check result information, and send the ECS finish flag signal and the check result information to the outside in response to a mode register read command received from the outside;
the second register circuit is configured to store an ECS configuration parameter;
the start circuit is connected to the second register circuit, and is configured to parse the ECS configuration parameter when the ECS start flag signal sent from the outside is received, to generate an ECS start signal; and
the ECS circuit is connected to the start circuit, and is configured to: receive the ECS start signal, and control, based on the ECS start signal, the memory chip to enter a new ECS operation cycle;
the command generation circuit comprises a first command generation circuit and a second command generation circuit;
the first command generation circuit is connected to the start circuit, and is configured to: receive the refresh command, and generate one ECS command signal by adopting a next refresh command at an interval;
the second command generation circuit is connected to the first command generation circuit, and is configured to: receive the ECS command signal, and generate an internal command signal based on the ECS command signal; and
the counting circuit is specifically configured to increase the address count value by one each time one internal command signal is received.

13. The memory chip according to claim 12, wherein
the control circuit is further configured to: receive an interval adjustment signal, and adjust a time interval between two consecutive ECS command signals based on the interval adjustment signal; and
the first command generation circuit is further configured to: receive the refresh command, and generate one ECS command signal by adopting a next refresh command at an interval of a second quantity of refresh commands, the second quantity being controlled by the interval adjustment signal; or
the first command generation circuit is specifically configured to: receive a preset clock signal and the refresh command and generate one ECS command signal by adopting a next refresh command when a first quantity of clock cycles of the preset clock signal pass, a clock cycle length of the preset clock signal being controlled by the interval adjustment signal, and/or the first quantity being controlled by the interval adjustment signal.

14. The memory chip according to claim 12, wherein the counting circuit comprises a column counting circuit, a row counting circuit, and a bank counting circuit, and the address count value comprises a column count value, a row count value, and a bank count value;
the column counting circuit is connected to the second command generation circuit, and is configured to: receive the internal command signal; count the internal command signal to generate the column count value; increase the column count value by one each time one internal command signal is received; and output one row counting signal and reset the column count value to zero when the column count value reaches a second preset value;
the row counting circuit is connected to the column counting circuit, and is configured to: receive the row counting signal; count the row counting signal to generate the row count value; increase the row count value by one each time one row counting signal is received; and output one bank counting signal and reset the row count value to zero when the row count value reaches a third preset value;
the bank counting circuit is connected to the row counting circuit, and is configured to: receive the bank counting signal; count the bank counting signal to generate the bank count value; increase the bank count value by one each time one bank counting signal is received; and output one ECS finish flag signal when the bank count value reaches a fourth preset value; and
the counting circuit is further configured to reset the address count value to zero after the memory chip receives the ECS start flag signal, wherein
the first preset value comprises the second preset value, the third preset value, and the fourth preset value.

15. An error check and scrub method, applied to a storage system, the storage system comprising a memory controller and a memory chip, and the method comprising:
generating an ECS finish flag signal and sending the ECS finish flag signal to the memory controller after the memory chip completes a current error check and scrub ECS operation cycle; and
generating, by the memory controller, an ECS start flag signal based on the ECS finish flag signal, and sending the ECS start flag signal to the memory chip, so that the memory chip enters a new ECS operation cycle.
